(19) United States
(12) Patent Application Publication
(10) Pub. No.: US 2020/0076401 A1
(43) Pub. Date: Mar. 5, 2020

(54) PIEZOELECTRIC DEVICE

(71) Applicant: NIHON DEMPA KOGYO CO., LTD., Tokyo (JP)

(72) Inventors: Hiromi OKUBO, Saitama (JP); SHUICHI MIZUSAWA, Saitama (JP)

(73) Assignee: NIHON DEMPA KOGYO CO., LTD., Tokyo (JP)

(21) Appl. No.: 16/554,574

(22) Filed: Aug. 28, 2019

(30) Foreign Application Priority Data
Aug. 30, 2018 (JP) 2018-160948

(51) Int. Cl. H03H 9/10; H03H 9/19

(52) U.S. Cl. CPC H03H 9/1021; H03H 9/19

(57) ABSTRACT

A piezoelectric device includes a cap, a base plate, and a flat bonding metal film. The cap has a flat plane area having a first width from a first outer peripheral end to a first inner peripheral end. The base plate has a first plane in contact with the cap and a second plane as an opposite surface of the first plane. The base plate has an outer periphery in a shape identical to the rectangular frame shape in plan view. The flat bonding metal film is formed on the first plane. The bonding metal film is formed in a rectangular frame shape in a size overlapping with the plane area. The bonding metal film has a second width from a second outer peripheral end to a second inner peripheral end. The second outer peripheral end is positioned outside the first outer peripheral end.

### CROSS-REFERENCE TO RELATED APPLICATIONS

This application claims the priority benefits of Japanese Patent Application No. 2018-160948, filed on Aug. 30, 2018. The entirety of the above-mentioned patent application is hereby incorporated by reference herein and made a part of this specification.

### TECHNICAL FIELD

This disclosure relates to a piezoelectric device such as a piezoelectric filter, a piezoelectric resonator, and a piezoelectric oscillator.

### DESCRIPTION OF THE RELATED ART

Piezoelectric devices, such as a piezoelectric filter, a piezoelectric resonator, a piezoelectric vibrating piece, a piezoelectric oscillator, and an acceleration sensor, using a piezoelectric material such as crystal are used in fields in an extremely wide range. One type of such piezoelectric devices is disclosed in, for example, Japanese Unexamined Patent Application Publication No. 2000-134055. This piezoelectric device includes a plate-shaped base plate and a metal cap. The base plate includes a bonding metal film formed of a metal film on a peripheral area. The metal cap has a dome shape where a peripheral area is bent downward, and a flange surface is formed on the peripheral area. The bonding metal film and the flange surface are sealed.

However, when an external pressure and the like is applied due to an insufficient sealing strength of the piezoelectric device, leakage possibly occurs between an inside of the piezoelectric device and external air. While enlarging the bonding metal film and the flange surface enhances a bonding strength of the base plate and the metal cap, this causes increase in size of the piezoelectric device.

A need thus exists for a piezoelectric device which is not susceptible to the drawback mentioned above.

### SUMMARY

According to an aspect of this disclosure, there is provided a piezoelectric device that includes a cap, a base plate in a flat plate shape, and a flat bonding metal film. The cap is formed in a rectangular frame shape in plan view. The cap has a flat plane area having a first width. The first width is from a first outer peripheral end to a first inner peripheral end. The cap covers a piezoelectric element. The base plate has a first plane in contact with the cap and a second plane as an opposite surface of the first plane. The base plate has an outer periphery in a shape identical to the rectangular frame shape in plan view. The flat bonding metal film is formed on the first plane. The bonding metal film is formed in a rectangular frame shape in a size overlapping with the plane area. The bonding metal film has a second width from a second outer peripheral end to a second inner peripheral end. The second outer peripheral end is positioned outside the first outer peripheral end.

### BRIEF DESCRIPTION OF THE DRAWINGS

The foregoing and additional features and characteristics of this disclosure will become more apparent from the following detailed description considered with reference to the accompanying drawings.

FIG. 1 is an exploded perspective view of a piezoelectric device 100.

FIG. 2 is a sectional drawing of a cap made of metal and its partial enlarged figure.

FIG. 3 is a sectional drawing of the piezoelectric device.

FIGS. 4A and 4B are enlarged sectional drawings of a bonding metal film and a flange surface.

### DESCRIPTION OF EMBODIMENTS

The following describes an embodiment of the disclosure with reference to the drawings. Each drawing used in the descriptions is merely illustrated schematically for understanding the embodiment, and a size, an angle, a thickness or similar factor is exaggeratedly illustrated. In each drawing used in the descriptions, like reference numerals designate corresponding or identical elements, and therefore such elements will not be further elaborated in some cases. Shapes, dimensions, materials, and similar factor described in the following embodiment are merely preferable examples within the scope of the disclosure.

[Configuration of Piezoelectric Device 100]

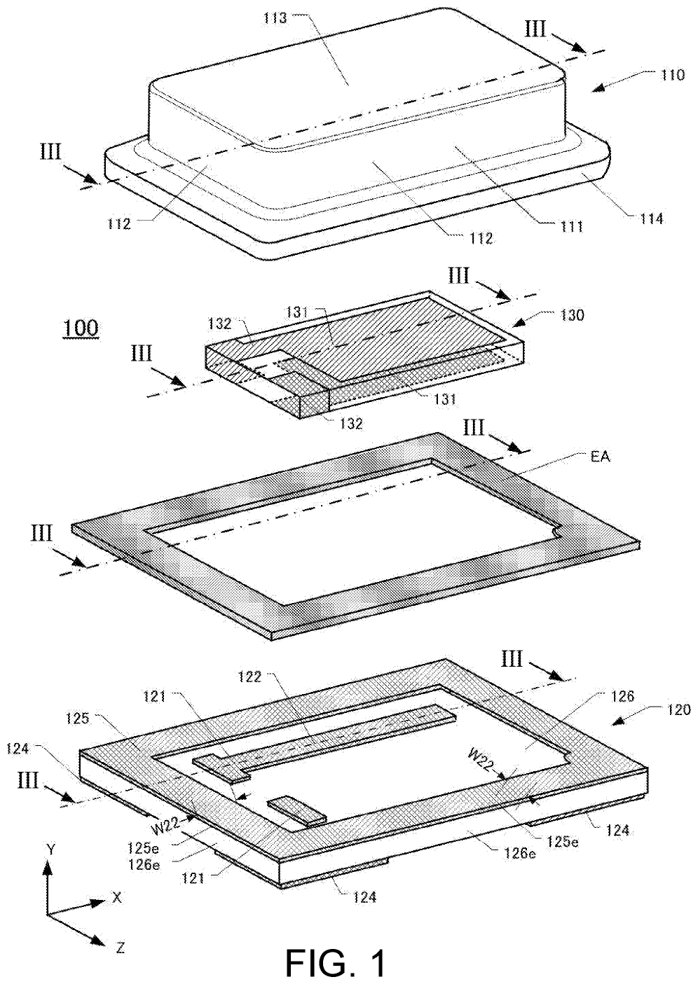

FIG. 1 is an e exploded perspective view of the piezoelectric device 100. The piezoelectric device 100 includes a cap 110 made of metal, a ceramic base plate 120, and a piezoelectric vibrating piece 130. For the piezoelectric vibrating piece 130, for example, a quartz-crystal vibrating piece of AT-cut, SC-cut, or similar cut is used. While the following representatively describes the quartz-crystal vibrating piece, this embodiment is applicable to the piezoelectric device using a piezoelectric piece, for example, a crystal filter or a crystal-controlled oscillator. The description will be given while defining a longitudinal direction of the piezoelectric device 100 as an X-axis direction, a height direction of the piezoelectric device 100 as a Y-axis direction, and a direction perpendicular to the X-axis direction and the Y-axis direction as a Z-axis direction.

In the piezoelectric device 100, the piezoelectric vibrating piece 130 is placed on a surface of a +Y-axis side of the ceramic base plate 120. Further, the cap 110 made of metal is placed on the surface of the +Y-axis side of the ceramic base plate 120 so as to seal the piezoelectric vibrating piece 130. The ceramic base plate 120 and the cap 110 made of metal are bonded via a eutectic alloy EA as a bonding agent. The piezoelectric device 100 is a surface mount type piezoelectric device mounted to a printed circuit board and the like. While FIG. 1 illustrates the eutectic alloy EA as the bonding agent in a flat plate frame shape, the eutectic alloy EA is disposed on at least one of a flange surface or a bonding metal film described later.

The cap 110 made of metal is pressed with a mold (not illustrated) to be formed in a box shape having a depressed portion 111 depressed in a +Y-axis direction. The cap 110 made of metal has four wall surfaces 112 that surround the depressed portion 111, a ceiling surface 113 bonded to sides on the +Y-axis sides of the respective wall surfaces 112, and a flange surface 114 formed in a ring shape on sides on −Y-axis sides of the respective wall surfaces 112 so as to be bent outward from the wall surfaces 112.

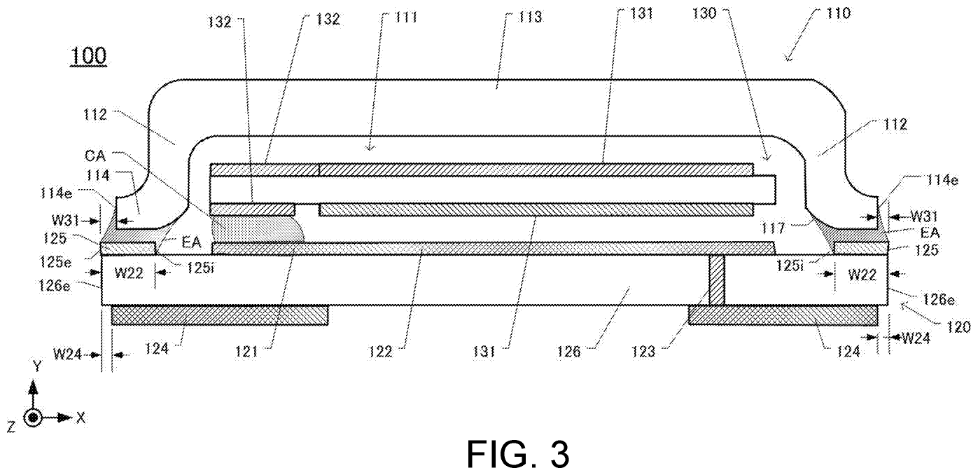

The ceramic base plate 120 has a rectangular shape in plan view, and includes a flat plate 126 that has upper and lower principal surfaces. The ceramic flat plate 126 includes a pair of connection pads 121 on a surface of a +Y-axis side. The connection pads 121 are each electrically connected to the piezoelectric vibrating piece 130 via a conductive adhesive CA (see FIG. 3). The ceramic base plate 120 includes four mounting terminals 124 on a surface of a −Y-axis side. The ceramic flat plate 126 includes a pair of through electrodes 123 (see FIG. 3) passing through in the Y-axis direction. The respective connection pads 121 are electrically connected to the mounting terminals 124 via the through electrodes 123 or via a wiring electrode 122 and the through electrodes 123. The four mounting terminals 124 are disposed in this embodiment. One of the four mounting terminals 124 may be a grounding terminal. The piezoelectric device 100 is mounted to the printed circuit board and the like via the mounting terminal 124 with a solder or the like.

A frame-shaped bonding metal film 125 is formed on an outer peripheral side on the surface of +Y-axis side of the flat plate 126 so as to surround the whole electrodes formed on the surface of the +Y-axis side of the ceramic base plate 120. This frame-shaped bonding metal film 125 is a surface facing the flange surface 114, and the bonding metal film 125 is bonded to the flange surface 114 with the eutectic alloy EA. The frame-shaped bonding metal film 125 is formed from a position of an outer peripheral end 126e of the flat plate 126 having a width W22. The frame-shaped bonding metal film 125 has a second outer peripheral end 125e at a position matching a position of the outer peripheral end 126e of the flat plate 126. However, the second outer peripheral end 125e of the bonding metal film 125 may be positioned slightly inside the outer peripheral end 126e of the flat plate 126. The connection pads 121, the wiring electrode 122, and the frame-shaped bonding metal film 125 are formed by screen-printing and the like. Their thicknesses (Y-axis direction) are about 10 μm. While a description is given using the ceramic base plate in the first embodiment, the base plate may be formed of glass or crystal.

The piezoelectric vibrating piece 130 includes excitation electrodes 131 on the surfaces of the +Y-axis side and the −Y-axis side, and extraction electrodes 132 are extracted from the respective excitation electrodes 131. The extraction electrode 132 is extracted from the excitation electrode 131 formed on the surface of the +Y-axis side of the piezoelectric vibrating piece 130 to the −X-axis side, and the extraction electrode 132 is further extracted to the surface of the −Y-axis side via a side surface of the −Z-axis side of the piezoelectric vibrating piece 130. The extraction electrode 132 extracted from the excitation electrode 131 formed on the surface of the −Y-axis side of the piezoelectric vibrating piece 130 extends from the excitation electrode 131 to the −X-axis side, and is further extracted to the surface of the +Y-axis side via a side surface of the +Z-axis side of the piezoelectric vibrating piece 130.

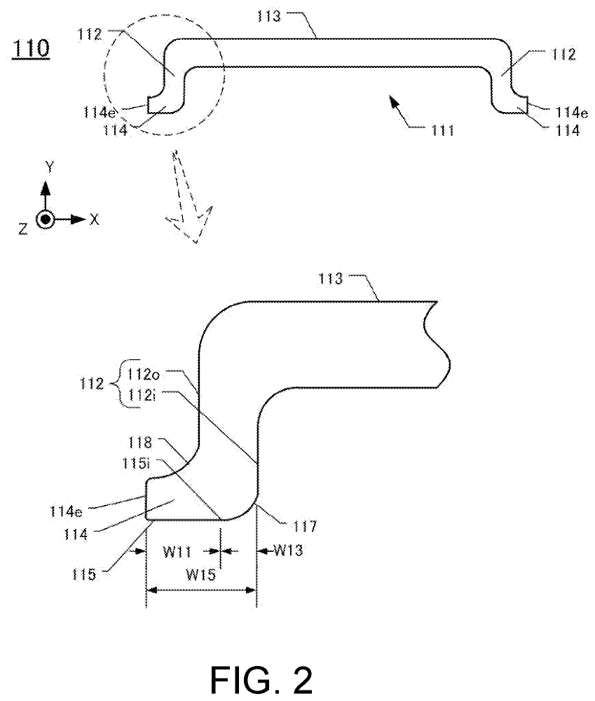

FIG. 2 is a sectional drawing of the cap made of metal taken along a line III-III of FIG. 1. The cap 110 made of metal is bonded to a top surface of the base plate 120 with the eutectic alloy EA to airtightly seal the piezoelectric vibrating piece 130 mounted on the top surface of the base plate 120.

The cap 110 made of metal is made of an alloy, for example, containing at least any of iron, nickel, or cobalt, and integratedly formed. The cap 110 made of metal airtightly seals the depressed portion 111 in a vacuum state or the depressed portion 111 where nitrogen gas or the like is filled. The ceiling surface 113 has a rectangular flat plate shape in plan view, and has a principal surface larger than the principal surface of the rectangular-shaped piezoelectric vibrating piece 130 and smaller than the top surface of the base plate 120 in size. The ceiling surface 113 has a lower surface on which the depressed portion 111 surrounded by the four wall surfaces 112 is formed.

The wall surfaces 112 form the depressed portion 111 on the lower surface of the cap 110 made of metal, and are disposed along an outer edge of the ceiling surface 113. In the depressed portion 111, the piezoelectric vibrating piece 130 mounted on the base plate 120 is housed. The flange surface 114 ensures an area for bonding the cap 110 made of metal and the base plate 120 to enhance a bonding strength. The flange surface 114 extends along outer peripheral surfaces of the wall surfaces 112 in an annular shape and toward outer peripheral sides of the wall surfaces 112.

Here, a method for manufacturing the cap 110 made of metal will be described. The cap 110 made of metal is manufactured by, for example, a presswork using a mold. The ceiling surface 113, the wall surfaces 112, and the flange surface 114 are formed by sandwiching and applying pressure to a flat plate with a pair of molds having a protruding part and a depressed part in a shape identical to that of the depressed portion 111 of the cap 110 made of metal. Afterwards, sand-blasting or the like is performed to increase a curvature of bending especially at a periphery of the flange surface 114, and Burrs caused in the presswork are removed. The cap 110 made of metal has the depressed portion 111 manufactured by what is called a drawing where the presswork is used to perform a plastic work on a flat plate.

A dimension of the completed cap 110 made of metal, especially, a dimension of the periphery of the flange surface 114 will be described with reference to the enlarged figure of FIG. 2. A part from the wall surface 112 to the flange surface 114 is bent at a right angle, and at its corner, an inner curved surface 117 and an outer curved surface 118 are formed on an inside and an outside. The inner curved surface 117 is a curved surface continuous from an inner sidewall surface 112i and preferred to have a large curvature such that a fillet of the eutectic alloy EA is easily formed as described later. The outer curved surface 118 is a curved surface from an outer sidewall surface 112o to a first outer peripheral end 114e of the flange surface 114, and formed not to have long lengths in the Z-axis direction and the Y-axis direction of the cap 110 made of metal. That is, on the upper side (+Y-axis side) of the flange surface 114, there is almost no plane area (XZ-plane) preferably. Meanwhile, on the lower side r (−Y-axis side) of the flange surface 114, a plane area (XZ-plane) 115 is formed. The plane area 115 has a width W11 from the first outer peripheral end 114e of the flange surface 114 to a first inner peripheral end 115i of the plane area 115, and the inner curved surface 117 is formed from this first inner peripheral end 115i. A width from the first outer peripheral end 114e of the flange surface 114 to the inner sidewall surface 112i of the wall surface 112 is indicated as a width W15. The inner curved surface 117 has a width W13 (=W15−W11) from the first inner peripheral end 115i of the plane area 115 to the inner sidewall surface 112i of the wall surface 112. Provisionally, when the base plate 120 has the length in the X-axis direction of 0.80 mm and the length in the Z-axis direction of 0.60 mm, the plane area 115 has the width W11 of 0.03 mm (30 μm) to 0.07 mm (70 μm), preferably about 0.05 mm. The inner curved surface 117 has the width W13 of 0.015 mm (15 μm) to 0.035 mm (35 μm), approximately ½ of the width W11 of the plane area 115, and preferably about 0.025 mm (25 μm). Therefore, the width W15 from the first outer peripheral end 114e of the flange surface 114 to the inner sidewall surface 112i of the wall surface 112 is preferably 0.045 mm (45 μm) to 0.105 mm (105 μm).

FIG. 3 is a sectional drawing of the piezoelectric device taken along the line III-III of FIG. 1. The piezoelectric vibrating piece 130 is placed on the surface of the +Y-axis side of the ceramic base plate 120. The extraction electrode 132 of the piezoelectric vibrating piece 130 is electrically connected to the connection pad 121 of the ceramic base plate 120 via the conductive adhesive CA. The excitation electrode 131 of the piezoelectric vibrating piece 130 is electrically connected to the mounting terminal 124 via the wiring electrode 122 and the through electrode 123. Then, the frame-shaped bonding metal film 125 is formed to have the width W22 from near the outer peripheral end 126e of the flat plate 126 to a second inner peripheral end 125i inside the bonding metal film 125. Provisionally, when the base plate 120 has the length in the X-axis direction of 0.80 mm and the length in the Z-axis direction of 0.60 mm, the frame-shaped bonding metal film 125 has the width W22 of 0.06 mm to 0.08 mm. The mounting terminal 124 is formed to be separated from the outer peripheral end 126e of the flat plate 126 by the width W24, for example, 0.02 mm.

A length of the cap 110 made of metal, that is, a length from one first outer peripheral end 114e of the flange surface 114 to the other first outer peripheral end 114e is shorter than a length from one outer peripheral end 126e of the flat plate 126 to the other outer peripheral end 126e. In the X-axis direction illustrated in FIG. 3, a length in the X-axis direction of the ceramic base plate 120 is longer than the length in the X-axis direction of the cap 110 made of metal by a length about double of the width W31. In other words, the width W31 is a length from the second outer peripheral end 125e of the bonding metal film 125 to the first outer peripheral end 114e of the flange surface 114, and the second outer peripheral end 125e of the bonding metal film 125 is positioned outside the first outer peripheral end 114e of the cap 110 made of metal.

As described above, the plane area 115 of the cap 110 has the width W11 of 0.03 mm (30 μm) to 0.07 mm (70 μm), preferably about 0.05 mm (50 μm). Meanwhile, the frame-shaped bonding metal film 125 has the width W22 of 0.06 mm (60 μm) to 0.08 mm (80 μm). That is, the width W22 of the frame-shaped bonding metal film 125 is preferred to be greater than the width W11 of the plane area 115. This is for easily forming the fillet (shape spreading toward the end formed by the molten bonding agent) of the eutectic alloy EA on the flange surface 114 of the cap 110. Here, a description will be given of a positional relation between an inner end of the plane area 115 of the cap 110 and an inner end of the frame-shaped bonding metal film 125. The first inner peripheral end 115i of the plane area 115 and the second inner peripheral end 125i of the frame-shaped bonding metal film 125 are arranged on an approximately identical position. Alternatively, the second inner peripheral end 125i of the frame-shaped bonding metal film 125 is preferred to be arranged outside the first inner peripheral end 115i of the plane area 115. This is also for easily forming the fillet of the eutectic alloy EA on the flange surface 114 of the cap 110, and for easily forming the fillet of the eutectic alloy EA on the inner end of the frame-shaped bonding metal film 125. For such a positional relation, the width W15 from the inner sidewall surface 112i of the cap 110 to the first outer peripheral end 114e is preferred to be greater than the width W22 of the bonding metal film 125.

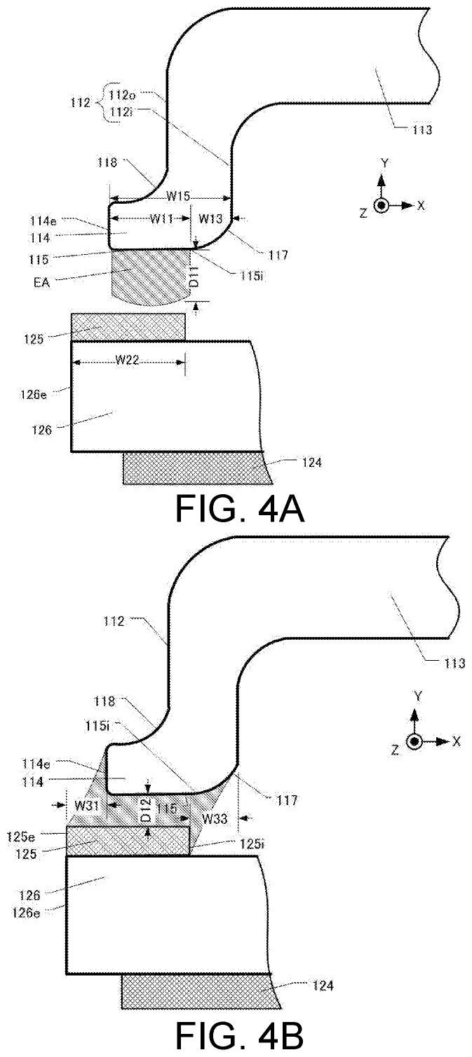

FIGS. 4A and 4B are partially enlarged figures of the flange surface of the cap made of metal and the base plate of FIG. 3. FIG. 4A is a drawing illustrating a state where the eutectic alloy EA is disposed on the plane area 115 of the cap 110 made of metal and before this cap 110 made of metal is placed on the base plate 120. FIG. 4B is a drawing illustrating a state after this cap 110 made of metal is placed on the base plate 120. While the illustration is omitted, the eutectic alloy EA may be disposed on not the plane area 115 of the cap 110 made of metal but the frame-shaped bonding metal film 125, or the eutectic alloy EA may be disposed on both of them.

The eutectic alloy EA has a melting point higher than a melting point 250° C. to 280° C. of an alloy (for example, lead-free solder) used for connecting the mounting terminal 124 to an external board of external electronic equipment and the like. For the eutectic alloy EA, for example, a zinc-aluminum (ZnAl) alloy, a gold-tin (AuSn) alloy, or a copper-tin (CuSn) alloy having the melting point above 300° C. (melting point above 400° C. after made to be an alloy) is preferable. The disposed eutectic alloy EA has a thickness D11 of, for example, 12 to 15 μm.

In sealing the cap 110 and the base plate 120, the flange surface 114 is placed on the frame-shaped bonding metal film 125, and the cap 110 and the base plate 120 are put into a predetermined sealing device. Then, when the eutectic alloy EA melts, the melted eutectic alloy EA flows to the second outer peripheral end 125e of the bonding metal film 125 to make a thickness D12 of the eutectic alloy EA about 10 μm as illustrated in FIG. 4B. However, as illustrated in FIG. 4B, in the piezoelectric device of this embodiment, the second outer peripheral end 125e of the bonding metal film 125 is positioned outside the first outer peripheral end 114e of the cap 110 by about a length of the width W31. Therefore, the fillet is formed also on the first outer peripheral end 114e of the flange surface 114, and formed along the inner curved surface 117. The fillet is formed also on the second inner peripheral end 125i of the bonding metal film 125. Accordingly, the cap 110 made of metal and the frame-shaped bonding metal film 125 are strongly sealed, thus the piezoelectric vibrating piece 130 is sealed in the depressed portion 111.

As described above, the length from the one first outer peripheral end 114e of the flange surface 114 to the other first outer peripheral end 114e is shorter than the length from the one outer peripheral end 126e of the flat plate 126 to the other outer peripheral end 126e by the length double of the width W31. On one side in the X-axis direction or the Z-axis direction, the width W31 is about ½ to ¼ of the width W22 of the frame-shaped bonding metal film 125. In view of this, in other words, the length of the cap 110 made of metal is shorter than the length of the ceramic base plate 120 by a length about one time to ½ of the width W22 of the frame-shaped bonding metal film 125. Provisionally, when the base plate 120 has the length in the X-axis direction of 0.80 mm and the length in the Z-axis direction of 0.60 mm, the width W31 is preferred to be 0.04 mm (40 μm) to 0.01 mm (10 μm), and further, the width W31 is further preferred to be 0.03 mm (30 μm) to 0.02 mm (20 μm). More preferably, the width W31 is about 0.025 mm (25 μm).

Next, a width W33 from the second inner peripheral end 125i of the frame-shaped bonding metal film 125 to the inner sidewall surface 112i of the cap 110 made of metal will be described. As described above, the second inner peripheral end 125i of the frame-shaped bonding metal film 125 is preferred to be positioned at a position approximately identical to or outside the position of the first inner peripheral end 115i of the plane area 115. In view of this, the width W33 from the second inner peripheral end 125i of the frame-shaped bonding metal film 125 to the inner sidewall surface 112i of the cap 110 made of metal is longer than the width W31 from the outer peripheral end 126e of the flat plate 126 to the first outer peripheral end 114e of the flange surface 114. Since the width W33 is approximately identical to or longer than the width W13 of the inner curved surface 117, when the base plate 120 provisionally has the length in the X-axis direction of 0.80 mm and the length in the Z-axis direction of 0.60 mm, the width W33 is 0.015 mm (15 μm) to 0.040 mm (40 μm), and preferably about 0.03 mm (30 μm). A ratio W31:W33 is 0.25 (10/40) to 2.6 (40/15), and preferably about 0.83 (25/30).

While the base plate described in this embodiment does not include castellation electrodes on four corners, this embodiment is also applicable to a base plate including a castellation electrode. This embodiment is also applicable to a base plate where an upper ceramic plate and a lower ceramic plate are combined and a through electrode and a castellation electrode are included.

The second inner peripheral end may be positioned at a position identical to a position of the first inner peripheral end or positioned outside the first inner peripheral end. Furthermore, a second width may be greater than a first width. A third width from the inner sidewall surface of the cap to the first outer peripheral end may be greater than the second width.

The width W31 from the second outer peripheral end to the first outer peripheral end may be 10 to 40 μm (25±15 μm). Furthermore, when a length from the second inner peripheral end to the inner sidewall surface of the cap is the width W33, the ratio W31:W33 may be 0.25 to 2.60.

The piezoelectric device according to the embodiment ensures the enhanced bonding strength of the base plate and the cap without increase in size.

The principles, preferred embodiment and mode of operation of the present invention have been described in the foregoing specification. However, the invention which is intended to be protected is not to be construed as limited to the particular embodiments disclosed. Further, the embodiments described herein are to be regarded as illustrative rather than restrictive. Variations and changes may be made by others, and equivalents employed, without departing from the spirit of the present invention. Accordingly, it is expressly intended that all such variations, changes and equivalents which fall within the spirit and scope of the present invention as defined in the claims, be embraced thereby.

What is claimed is:

1. A piezoelectric device, comprising:
a cap, formed in a rectangular frame shape in plan view, the cap having a flat plane area having a first width, the first width being from a first outer peripheral end to a first inner peripheral end, the cap covering a piezoelectric element;
a base plate in a flat plate shape, the base plate having a first plane in contact with the cap and a second plane as an opposite surface of the first plane, the base plate having an outer periphery in a shape identical to the rectangular frame shape in plan view; and
a flat bonding metal film formed on the first plane, the bonding metal film being formed in a rectangular frame shape in a size overlapping with the plane area, the bonding metal film having a second width from a second outer peripheral end to a second inner peripheral end, wherein
the second outer peripheral end is positioned outside the first outer peripheral end.

2. The piezoelectric device according to claim 1, wherein
the second inner peripheral end is positioned at a position identical to a position of the first inner peripheral end, or positioned outside the first inner peripheral end.

3. The piezoelectric device according to claim 1, wherein the second width is greater than the first width.

4. The piezoelectric device according to claim 1, wherein
a third width from an inner sidewall surface of the cap to the first outer peripheral end is greater than the second width.

5. The piezoelectric device according to claim 1, wherein
a width W31 from the second outer peripheral end to the first outer peripheral end is 10 μm to 40 μm.

6. The piezoelectric device according to claim 5, wherein
when a length from the second inner peripheral end to the inner sidewall surface of the cap is a width W33,
a ratio W31:W33 is 0.25 to 2.60.
